(19) United States
(12) Patent Application Publication
(10) Pub. No.: US 2024/0321989 A1
(43) Pub. Date: Sep. 26, 2024

(54) SEMICONDUCTOR DEVICE

(71) Applicant: SAMSUNG ELECTRONICS CO., LTD., Suwon-si (KR)

(72) Inventors: Gunho JO, Suwon-si (KR); Heesub KIM, Suwon-si (KR); Seunghyun LIM, Suwon-si (KR); Bomi KIM, Suwon-si (KR); Eunho CHO, Suwon-si (KR)

(73) Assignee: SAMSUNG ELECTRONICS CO., LTD., Suwon-si (KR)

(21) Appl. No.: 18/397,561

(22) Filed: Dec. 27, 2023

(30) Foreign Application Priority Data
Mar. 24, 2023 (KR) 10-20230038591

(51) Int. Cl. H01L 29/423; H01L 29/06; H01L 29/417; H01L 29/66; H01L 29/775

(52) U.S. Cl. CPC H01L 29/42392; H01L 29/0673; H01L 29/41733; H01L 29/66439; H01L 29/66545; H01L 29/775

(57) ABSTRACT

A semiconductor device includes a substrate, an active pattern including a lower pattern extending in a first direction and a plurality of sheet patterns above an upper surface of the lower pattern and spaced apart from the lower pattern in a second direction substantially perpendicular to the first direction, a gate structure on the lower pattern and including a gate electrode and a gate insulating film, the gate electrode and the gate insulating film at least partially surrounding the plurality of sheet patterns, a first gate capping pattern on the gate structure and above the plurality of sheet patterns in the second direction, a gate spacer extending along a side wall of the gate structure, and a second gate capping pattern extending along an upper surface of the gate structure and an upper surface of the first gate capping pattern.

### CROSS-REFERENCE TO RELATED APPLICATION

This application is based on and claims priority to Korean Patent Application No. 10-2023-0038591, filed on Mar. 24, 2023 in the Korean Intellectual Property Office, the disclosure of which is incorporated herein by reference in its entirety.

### BACKGROUND

### 1. Field

Example embodiments of the disclosure relate to a semiconductor device, and more specifically, to a semiconductor device including an multi-bridge channel field effect transistor (MBCFET™).

### 2. Description the Related Art

To increase a density of semiconductor devices, a multi-gate transistor may be implemented in which a multi-channel active pattern (or a silicon body) having a fin or nanowire shape is formed on a substrate and a gate is formed on a surface of a multi-channel active pattern. However, recess variation, metal climbs, and dishing may occur in such devices.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with improved element performance and reliability.

Additional aspects will be set forth in part in the description which follows and, in part, will be apparent from the description, or may be learned by practice of the presented embodiments.

According to an aspect of an example embodiment, a semiconductor device may include a substrate, an active pattern including a lower pattern extending in a first direction and a plurality of sheet patterns above an upper surface of the lower pattern and spaced apart from the lower pattern in a second direction substantially perpendicular to the first direction, a gate structure on the lower pattern and including a gate electrode and a gate insulating film, the gate electrode and the gate insulating film at least partially surrounding the plurality of sheet patterns, a first gate capping pattern on the gate structure and above the plurality of sheet patterns in the second direction, a gate spacer extending along a side wall of the gate structure, a second gate capping pattern extending along an upper surface of the gate structure and an upper surface of the first gate capping pattern, a source/drain pattern on at least one side of the gate structure, and an etching stop film on the source/drain pattern and a first side wall of the first gate capping pattern, where the second gate capping pattern at least partially covers an upper surface of the gate spacer and from the lower pattern, the upper surface of the first gate capping pattern is higher than the upper surface of the gate structure.

According to an aspect of an example embodiment, a semiconductor device may include a substrate, an active pattern including a lower pattern extending in a first direction and a plurality of sheet patterns above an upper surface of the lower pattern and spaced apart from the lower pattern in a second direction substantially perpendicular to the first direction, a gate structure on the lower pattern and including a gate electrode and a gate insulating film, the gate electrode and the gate insulating film at least partially surrounding the plurality of sheet patterns, a first gate capping pattern on the gate structure and above the plurality of sheet patterns in the second direction, a gate spacer extending along a side wall of the gate structure, a second gate capping pattern extending along an upper surface of the gate structure and an upper surface of the first gate capping pattern, a source/drain pattern on at least one side of the gate structure, and an etching stop film on the source/drain pattern and a side wall of the first gate capping pattern, where the gate structure includes a plurality of inter-gate structures between the lower pattern and the plurality of sheet patterns, and between adjacent sheet patterns of the plurality of sheet patterns, the first gate capping pattern does not overlap the gate spacer in the second direction, and from the lower pattern, the upper surface of the first gate capping pattern is higher than the upper surface of the gate structure.

According to an aspect of an example embodiment, a semiconductor device may include a substrate, an active pattern including a lower pattern extending in a first direction and a plurality of sheet patterns above an upper surface of the lower pattern and spaced apart from the lower pattern in a second direction substantially perpendicular to the first direction, a field insulating film at least partially covering a side wall of the lower pattern, a gate structure on the lower pattern and the field insulating film, extending in a third direction, and including a gate electrode and a gate insulating film, the gate electrode and the gate insulating film at least partially surrounding the plurality of sheet patterns, a first gate capping pattern on the gate structure and above the plurality of sheet patterns in the second direction, a gate spacer extending along a side wall of the gate structure in the third direction, a second gate capping pattern extending along an upper surface of the gate structure and an upper surface of the first gate capping pattern, a gate contact penetrating the first gate capping pattern and the second gate capping pattern on the gate electrode, the gate contact being connected to the gate electrode, a source/drain pattern on at least one side of the gate structure, an etching stop film on the source/drain pattern and a side wall of the first gate capping pattern, and a source/drain contact on the source/drain pattern and connected to the source/drain pattern, where the first gate capping pattern does not overlap the field insulating film in the second direction, a second gate capping pattern at least partially covers an upper surface of the gate spacer, a side wall of the second gate capping pattern contacts the etching stop film and from the lower pattern, the upper surface of the first gate capping pattern is higher than the upper surface of the gate structure.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating the semiconductor device according to some embodiments;

FIG. 2 is a cross-sectional view taken along line A-A of FIG. 1 according to some embodiments;

FIG. 3 is a cross-sectional view taken along line B-B of FIG. 1 according to some embodiments;

FIG. 4 is a cross-sectional view taken along line C-C of FIG. 1 according to some embodiments;

FIG. 5 is a diagram illustrating a semiconductor device according to some embodiments;

FIG. 6 is a diagram illustrating a semiconductor device according to some embodiments;

FIG. 7 is a diagram illustrating a semiconductor device according to some embodiments;

FIG. 8 is a diagram illustrating a semiconductor device according to some embodiments;

FIG. 9 is a diagram illustrating a semiconductor device according to some embodiments; and

FIG. 10 to 31 are diagrams illustrating a method of fabricating a semiconductor device according to some embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

A semiconductor device according to some embodiments may include a tunneling transistor (FET), a three-dimensional (3D) transistor or a two-dimensional (2D) material-based transistor (e.g., 2D material-based FET), and a heterogeneous structure thereof. Further, the semiconductor device according to some embodiments may include a bipolar junction transistor, a lateral double diffused transistor (LDMOS), and the like.

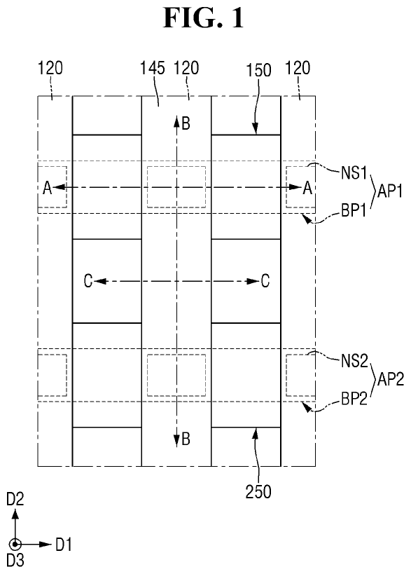

A semiconductor device according to some embodiments will be described with reference to FIGS. 1 to 4.

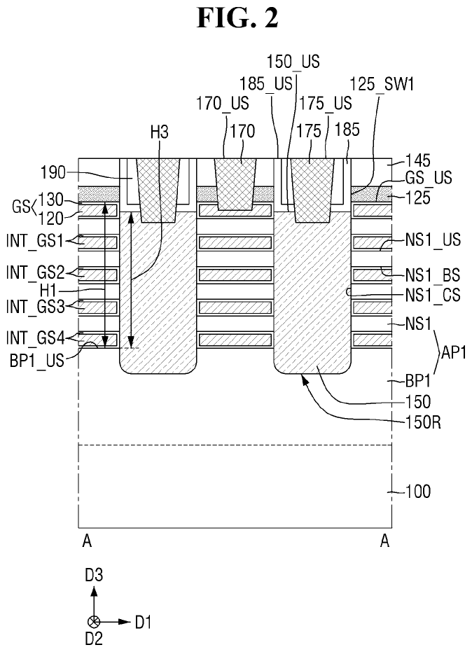

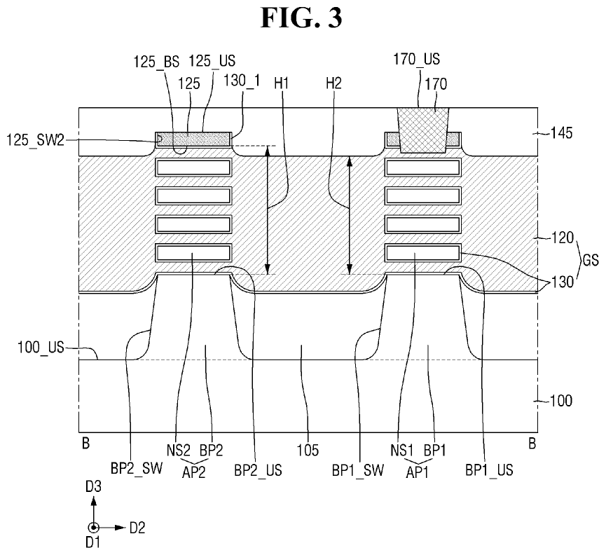

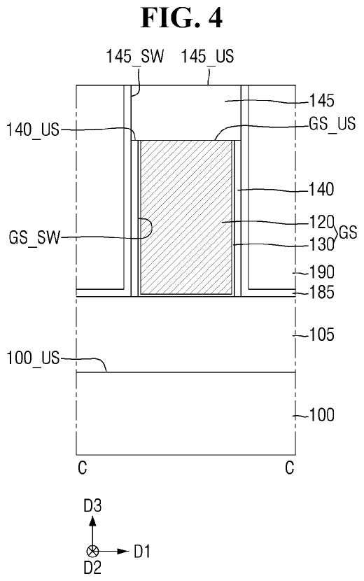

FIG. 1 is a plan view illustrating the semiconductor device according to some embodiments. FIG. 2 is a cross-sectional view taken along line A-A of FIG. 1 according to some embodiments. FIG. 3 is a cross-sectional view taken along line B-B of FIG. 1 according to some embodiments. FIG. 4 is a cross-sectional view taken along line C-C of FIG. 1 according to some embodiments.

To clearly depict aspects of the semiconductor device, a gate insulating film 130, a gate contact 170, a source/drain contact 175, an etching stop film 185, an interlayer insulating film 190, and the like, are not shown in FIG. 1, but are shown in other figures.

Referring to FIGS. 1 to 4, the semiconductor device according to some embodiments may include a first active pattern AP1, a second active pattern AP2, a plurality of gate structures GS, a first gate capping pattern 125, and a first source/drain pattern 150.

The substrate 100 may be a bulk silicon or a silicon-on-insulator (SOI). The substrate 100 may be a silicon substrate, or may include other materials, such as silicon germanium, silicon germanium on insulator (SGOI), indium antimonide, lead tellurium compounds, indium arsenide, indium phosphide, gallium arsenide, gallium antimonide, etc. In the semiconductor devices according to some embodiments, the substrate 100 may be an insulating substrate. The insulating substrate may include an insulating material.

A first active pattern AP1 and a second active pattern AP2 may be disposed on the substrate 100. Each of the first active pattern AP1 and the second active pattern AP2 may extend in a first direction D1.

The first active pattern AP1 and the second active pattern AP2 may be disposed to be spaced apart from each other in a second direction D2. For example, the first direction D1 may be a direction that intersects the second direction D2. The first active pattern AP1 may be adjacent to the second active pattern AP2 in the second direction D2.

As an example, one of the first active pattern AP1 and the second active pattern AP2 may correspond to a region in which a p-type metal-oxide-semiconductor (MOS) (PMOS) is formed, and the other may correspond to a region in which an n-type MOS (NMOS) is formed. As another example, the first active pattern AP1 and the second active pattern AP2 may correspond to regions in which an NMOS is formed. As yet another example, the first active pattern AP1 and the second active pattern AP2 may correspond to regions in which the PMOS is formed.

The first active pattern AP1 and the second active pattern AP2 may be multi-channel active patterns. The first active pattern AP1 may include a first lower pattern BP1 and a plurality of first sheet patterns NS1. The second active pattern AP2 may include a second lower pattern BP2 and a plurality of second sheet patterns NS2.

The first lower pattern BP1 and the second lower pattern BP2 may protrude from the substrate 100. Each of the first lower pattern BP1 and the second lower pattern BP2 may extend in the first direction D1.

The first lower pattern BP1 may be spaced apart from the second lower pattern BP2 in the second direction D2. The first lower pattern BP1 and the second lower pattern BP2 may each be separated by fin trenches extending in the first direction D1.

A plurality of first sheet patterns NS1 may be disposed on the first lower pattern BP1. The plurality of first sheet patterns NS1 may be spaced apart from the first lower pattern BP1 in a third direction D3. The plurality of first sheet patterns NS1 spaced apart from each other may be arranged in the third direction D3 above an upper surface BP1_US of the first lower pattern BP1.

A plurality of second sheet patterns NS2 may be disposed on the second lower pattern BP2. The plurality of second sheet patterns NS2 may be spaced apart from the second lower patterns BP2 in the third direction D3. The plurality of second sheet patterns NS2 spaced apart from each other may be arranged in the third direction D3 above an upper surface BP2_US of the second lower pattern BP2.

Each first sheet pattern NS1 may include a plurality of nanosheets sequentially disposed in the third direction D3. Each second sheet pattern NS2 may include a plurality of nanosheets sequentially disposed in the third direction D3.

The third direction D3 may be a direction that intersects the first direction D1 and the second direction D2. For example, the third direction D3 may be a thickness direction of the substrate 100. The first direction D1 may be a direction that intersects the second direction D2.

Each first sheet pattern NS1 may include an upper surface NS1_US and a lower surface NS1_BS. The upper surface NS1_US of the first sheet pattern NS1 may be a surface that is opposite to the lower surface NS1_BS of the first sheet pattern NS1 in the third direction D3. Each first sheet pattern NS1 may include connecting surfaces NS1_CS opposite to each other in the first direction D1.

The upper surface NS1_US of the first sheet pattern NS1 and the lower surface NS1_BS of the first sheet pattern NS1 may be connected by the connecting surface NS1_CS of the first sheet pattern NS1. The connecting surface NS1_CS of the first sheet pattern NS1 may be connected to and may contact a first source/drain pattern 150, which will be described below. The connecting surface NS1_CS of the first sheet pattern NS1 may be a boundary surface between the first sheet pattern NS1 and the first source/drain pattern 150.

Aspects of the second sheet pattern NS2 may be substantially the same as aspects of the first sheet pattern NS1.

Although four first sheet patterns NS1 and four second sheet patterns NS2 are each shown as being disposed in the third direction D3, embodiments are not limited thereto.

Each of the first lower pattern BP1 and the second lower pattern BP2 may be formed by etching a portion of the substrate 100, and may include an epitaxial layer grown from the substrate 100. Each of the first lower pattern BP1 and the second lower pattern BP2 may include silicon or germanium (i.e., an elemental semiconductor material). Each of the first lower pattern BP1 and the second lower pattern BP2 may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, at least one of a binary compound, a ternary compound and a quaternary compound formed by combining at least one of aluminum (Al), gallium (Ga) and indium (In) as a group III element with one of phosphorus (P), arsenic (As) and antimony (Sb) as a group V element.

Each first sheet pattern NS1 may include one of silicon or germanium, a group IV-IV compound semiconductor or a group III-V compound semiconductor. Each second sheet pattern NS2 may include one of silicon or germanium, a group IV-IV compound semiconductor or a group III-V compound semiconductor.

Each first sheet pattern NS1 may include the same material as the first lower pattern BP1, and may include a material different from the first lower pattern BP1. Each second sheet pattern NS2 may include the same material as the second lower pattern BP2, and may include a material different from the second lower pattern BP2.

As an example, the first sheet pattern NS1 and the second sheet pattern NS2 may include the same material. As another example, the first sheet pattern NS1 may include a material different from the second sheet pattern NS2.

In the semiconductor device according to some embodiments, the first lower pattern BP1 and the second lower pattern BP2 may be silicon lower patterns including silicon, and the first sheet pattern NS1 and the second sheet pattern NS2 may be silicon sheet patterns including silicon.

The first active pattern AP1 is described as exemplary, and the description may similarly apply to the second active pattern AP2 or other active patterns as will be understood by one of ordinary skill in the art from the disclosure herein. A width of the first sheet pattern NS1 in the second direction D2 may increase or decrease in proportion to a width of the first lower pattern BP1 in the second direction D2. As an example, although the first sheet patterns NS1 stacked in the third direction D3 are shown to have the same width in the second direction D2, embodiments are not limited thereto. The width in the second direction D2 of the first sheet patterns NS1 stacked in the third direction D3 may decrease as the distance from the first lower pattern BP1 increases.

A field insulating film 105 may be formed on the substrate 100. The field insulating film 105 may be disposed on side walls BP1_SW of the first lower pattern BP1 and side walls BP2_SW of the second lower pattern. The field insulating film 105 may cover or at least partially cover the side walls BP1_SW of the first lower pattern BP1 and the side walls BP2_SW of the second lower pattern. In some embodiments, the field insulating film 105 may not be disposed on the upper surface BP1_US of the first lower pattern BP1 and the upper surface BP2_US of the second lower pattern BP2.

As an example, the field insulating film 105 may entirely cover the side walls BP1_SW of the first lower pattern BP1 and the side walls BP2_SW of the second lower pattern along the first direction D1. The field insulating film 105 may partially cover the side walls BP1_SW of the first lower pattern BP1. The field insulating film 105 may partially cover the side walls BP2_SW of the second lower pattern. In such a case, a portion of the first lower pattern BP1 and a portion of the second lower pattern BP2 may protrude above the upper surface of the field insulating film 105 in the third direction D3.

Each first sheet pattern NS1 and each second sheet pattern NS2 may be disposed to be above the upper surface of the field insulating film 105. The field insulating film 105 may include, for example, an oxide film, a nitride film, an oxynitride film or a combination thereof. Although the field insulating film 105 is shown as a single film, embodiments are not limited thereto.

A plurality of gate structures GS may be disposed on the substrate 100. Each gate structure GS may extend in the second direction D2. The gate structures GS may be disposed to be spaced apart in the first direction D1. The gate structures GS may be adjacent to each other in the first direction D1.

The gate structure GS may be disposed on the first active pattern AP1 and the second active pattern AP2. The gate structure GS may intersect the first active pattern AP1 and the second active pattern AP2.

The gate structure GS may intersect the first lower pattern BP1 and the second lower pattern BP2. The gate structure GS may surround or at least partially surround each of the first sheet pattern NS1 and the second sheet pattern NS2. The gate structure GS may include, for example, a gate electrode 120 and a gate insulating film 130.

Although the gate structure GS is shown as being disposed over the first active pattern AP1 and the second active pattern AP2, embodiments are not limited thereto. That is, the gate structure GS may be separated into two portions, and the first portion of the gate structure GS intersecting the first active pattern AP1 may be spaced apart from the second portion of gate structure GS intersecting the second active pattern AP2 in the second direction D2.

The gate structure GS may include inter-gate structures INT_GS1, INT_GS2, INT_GS3 and INT_GS4, which may be disposed between the first sheet patterns NS1 that are adjacent to each other in the third direction D3, as well as between the first lower pattern BP1 and the first sheet pattern NS1 (i.e., between the first lower pattern BP1 and the lowest first sheet pattern NS1 with respect to the third direction D3). That is, the inter-gate structures (e.g., INT_GS1, INT_GS2, INT_GS3 and INT_GS4) may be disposed between the upper surface BP1_US of the first lower pattern BP1 and the lower surface NS1_BS of the first sheet pattern NS1 at the lowest position in the third direction D3 among the first sheet patterns NS1, as well as between the upper surfaces NS1_US of the first sheet patterns NS1 and the lower surfaces NS1_BS of the first sheet patterns NS1 that face each other in the third direction D3.

The number of inter-gate structures INT_GS1, INT_GS2, INT_GS3 and INT_GS4 may be proportional to the number of first sheet patterns NS1 included in the first active pattern AP. For example, when the number of first sheet patterns NS1 is four, the gate structures GS may include first to fourth inter-gate structures INT_GS1, INT_GS2, INT_GS3 and INT_GS4. Since the first active pattern AP1 includes a plurality of first sheet patterns NS1, the gate structure GS may include a plurality of inter-gate structures INT_GS1, INT_GS2, INT_GS3 and INT_GS4.

In the semiconductor device according to some embodiments, the inter-gate structures INT_GS1, INT_GS2, INT_GS3 and INT_GS4 may contact the first source/drain pattern 150, which will be described below. For example, the inter-gate structures INT_GS1, INT_GS2, INT_GS3 and INT_GS4 may directly contact the first source/drain patterns 150. The inter-gate structures INT_GS1, INT_GS2, INT_GS3 and INT_GS4 may contact the upper surface BP1_US of the first lower pattern BP1, the upper surface NS1_US of the first sheet pattern NS1, and the lower surface NS1_BS of the first sheet pattern NS1.

For convenience of description, a case where the number of inter-gate structures INT_GS1, INT_GS2, INT_GS3 and INT_GS4 is four is described.

The gate structure GS may include a first inter-gate structure INT_GS1, a second inter-gate structure INT_GS2, a third inter-gate structure INT_GS3, and a fourth inter-gate structure INT_GS4. The first inter-gate structure INT_GS1, the second inter-gate structure INT_GS2, the third inter-gate structure INT_GS3, and the fourth inter-gate structure INT_GS4 may be sequentially disposed on the first lower pattern BP1.

The fourth inter-gate structure INT_GS4 may be disposed between the first lower pattern BP1 and the first sheet pattern NS1. The fourth inter-gate structure INT_GS4 may be the lowermost of the inter-gate structures INT_GS1, INT_GS2, INT_GS3 and INT_GS4 in the third direction D3. The fourth inter-gate structure INT_GS4 may contact the upper surface BP1_US of the first lower pattern BP1.

The first inter-gate structure INT_GS1, the second inter-gate structure INT_GS2, and the third inter-gate structure INT_GS3 may be disposed between the first sheet patterns NS1 adjacent to each other in the third direction D3. The first inter-gate structure INT_GS1 may be the uppermost of the inter-gate structures INT_GS1, INT_GS2, INT_GS3 and INT_GS4 in the third direction D3. The first inter-gate structure INT_GS1 may contact the lower surface NS1_BS of the uppermost first sheet pattern NS1. The second inter-gate structure INT_GS2 may be disposed between the first inter-gate structure INT_GS1 and the third inter-gate structure INT_GS3.

The inter-gate structures INT_GS1, INT_GS2, INT_GS3 and INT_GS4 may include a gate electrode 120 and a gate insulating film 130 that are disposed between adjacent first sheet patterns NS1 and between the first lower pattern BP1 and the first sheet pattern NS1.

In the semiconductor device according to some embodiments, widths of each of the first to fourth inter-gate structures INT_GS1, INT_GS2, INT_GS3 and INT_GS4 in the first direction D1 may be the same or substantially the same as each other. The widths of each of the first to fourth inter-gate structures INT_GS1, INT_GS2, INT_GS3 and INT_GS4 in the first direction D1 may be the same or substantially the same as the width of the first sheet pattern NS1 in the first direction D1. However, embodiments are not limited thereto.

In the semiconductor device according to some embodiments, the width of the fourth inter-gate structure INT_GS4 in the first direction D1 may be greater than that of an adjacent inter-gate structure (e.g., the third inter-gate structure INT_GS3) in the first direction D1.

The above description regarding the first active pattern AP1 and the gate structure GS may also be applied to the second active pattern AP2 and the gate structure GS.

The gate electrode 120 may be formed on the first lower pattern BP1 and the second lower pattern BP2. The gate electrode 120 may intersect the first lower pattern BP1 and the second lower pattern BP2. The gate electrode 120 may surround or at least partially surround the first sheet pattern NS1 and the second sheet pattern NS2.

The first active pattern AP1 will be described as an example, and the corresponding description may be applied to the second active pattern AP2 and/or other active patterns that may be implemented. A portion of the gate electrode 120 may be disposed between adjacent first sheet patterns NS1, and between the first lower pattern BP1 and the lowermost first sheet pattern NS1. That is, a portion of the gate electrode 120 may be disposed between the upper surface BS1_US of the first lower pattern BP1 and the lower surface NS1_BS of the lowermost first sheet pattern NS1. When the first sheet pattern NS1 includes a first sub-sheet pattern and a second sub-sheet pattern adjacent to each other in the third direction D3, a portion of the gate electrode 120 may be disposed between the upper surface NS1_US of the first sub-sheet pattern and the lower surface NS1_BS of the second sheet pattern that face each other. A first sub-sheet pattern may be the lowermost first sheet pattern NS1, or may not be the lowermost first sheet pattern NS1. Also, a portion of the gate electrode 120 may be disposed between a first gate capping pattern 125 and an uppermost sheet pattern of the first sheet pattern NS1.

The gate electrode 120 may include at least one of metal, metal alloy, conductive metal nitride, metal silicide, doped semiconductor material, conductive metal oxide, and conductive metal oxynitride. The gate electrode 120 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and the conductive metal oxynitride may include, but are not limited to, oxidized forms of the aforementioned materials.

The gate electrode 120 may be disposed on both sides of a first source/drain pattern 150, which will be described below. The gate structure GS may be disposed on both sides of the first source/drain pattern 150 in the first direction D1.

As an example, the gate electrodes 120 disposed on both sides of the first source/drain pattern 150 may all be normal gate electrodes used as a gate of a transistor. As another example, the gate electrode 120 disposed on one side of the first source/drain pattern 150 is used as a gate of a transistor, and the gate electrode 120 disposed on the other side of the first source/drain pattern 150 may be a dummy gate electrode.

The above description of the relationship between the first source/drain pattern 150 and the gate electrode 120 may also be applied between the second source/drain pattern 250 and the gate electrode 120.

The gate insulating film 130 may extend along the upper surface of the field insulating film 105, the upper surface BP1_US of the first lower pattern BP1, and the upper surface BP2_US of the second lower pattern BP2 in the second direction D2 as shown in FIG. 3. The gate insulating film 130 may surround or at least partially surround the first sheet pattern NS1 and the second sheet pattern NS2. That is, the gate insulating film 130 may be disposed along the periphery of the first sheet pattern NS1 and the periphery of the second sheet pattern NS2. The gate electrode 120 may be disposed on the gate insulating film 130.

The first active pattern AP1 will be described as an example, and the corresponding description may be applied to the second active pattern AP2 and/or other active patterns that may be implemented. A portion of the gate insulating film 130 may be disposed between the first sheet patterns NS1 adjacent to each other in the third direction D3, as well as between the first lower pattern BP1 and the lowermost first sheet pattern NS1. When the first sheet pattern NS1 includes a first sub-sheet pattern and a second sub-sheet pattern that are adjacent to each other, a portion of the gate insulating film 130 may extend along the upper surface NS1_US of the first sub-sheet pattern and the lower surface NS1_BS of the second sub-sheet pattern that face each other.

Although the gate insulating film 130 is shown as a single film, embodiments are not limited thereto. The gate insulating film 130 may include an interfacial insulating film and a high dielectric constant insulating film. The interfacial insulating film may be disposed between the high dielectric constant insulating film and the sheet patterns NS1 and NS2.

The gate insulating film 130 may include silicon oxide, silicon oxynitride, silicon nitride, or a high dielectric constant material having a dielectric constant greater than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

A semiconductor device according to some embodiments may include a negative capacitance (NC) FET using a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) under 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. As an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further be doped with a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. A ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. A thickness of the ferroelectric material film may be, for example, about 0.5 to 10 nm. Since a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

A second gate capping pattern 145 may be disposed on the gate structure GS and the first gate capping pattern 125. The second gate capping pattern 145 may extend along the upper surface GS_US of the gate structure GS and the upper surface 125_US of the first gate capping pattern 125. That is, the second gate capping pattern 145 may extend in the second direction D2. The second gate capping pattern 145 may cover or at least partially cover the upper surface 125_US of the first gate capping pattern 125.

The second gate capping pattern 145 may cover or at least partially cover the upper surface 140_US of the gate spacer 140 at a portion that overlaps the field insulating film 105. That is, the second gate capping pattern 145 may contact the upper surface 140_US of the gate spacer 140. A side wall 145_SW of the second gate capping pattern 145 may contact the etching stop film 185. In other words, the gate spacer 140 may not be disposed between the side wall 145_SW of the second gate capping pattern 145 and the etching stop film 185.

The second gate capping pattern 145 may include, for example, at least one of silicon oxide (SiO₂), silicon nitride (SiN), silicon oxynitride (SiON), silicon carbonitride (SiCN), silicon oxycarbonitride (SiOCN), oxycarbide (SiOC), and combinations thereof.

A first gate capping pattern 125 may be disposed on the gate structure GS. The first gate capping pattern 125 may be disposed between the upper surface GS_US of the gate structure GS and the second gate capping pattern 145. The second gate capping pattern 145 may be disposed on the gate structure GS and the first gate capping pattern 125.

The first gate capping pattern 125 may include an upper surface 125_US, a lower surface 125_BS, a first side wall 125_SW1, and a second side wall 125_SW2. The upper surface 125_US of the first gate capping pattern 125 may be a surface that is opposite to the lower surface 125_BS of the first gate capping pattern 125 in the third direction D3. The first side walls 125_SW1 of the first gate capping pattern 125 may be surfaces that are opposite to each other in the first direction D1. The second side walls 125_SW2 of the first gate capping pattern 125 may be surfaces that are opposite to each other in the second direction D2.

The upper surface 125_US of the first gate capping pattern 125 may face the second gate capping pattern 145. The lower surface 125_BS of the first gate capping pattern 125 may face the gate structure GS.

The lower surface 125_BS of the first gate capping pattern 125 may contact the upper surface GS_US of the gate structure. The upper surface 125_US of the first gate capping pattern 125 may contact the second gate capping pattern 145.

The first gate capping pattern 125 may overlap and/or be positioned above the first active pattern AP1 and the second active pattern AP2 in the third direction D3. For example, the first gate capping pattern 125 may overlap and/or be positioned above the first sheet pattern NS1 and the second sheet pattern NS2 in the third direction D3.

The first gate capping pattern 125 may not overlap the field insulating film 105 in the third direction D3. That is, the first gate capping pattern 125 may not overlap the upper surface of the field insulating film 105 in the third direction D3. Put alternatively, the first gate capping pattern 125 may have a horizontal width in the second direction D2 such that no portion of the first gate capping pattern 125 extends over the field insulating film 105. That is, the first gate capping pattern 125 may have a horizontal width in the second direction D2 that is less than or equal to the horizontal width of the lower pattern BP1 in the second direction D2.

In other words, when one gate structure GS overlaps the plurality of active patterns, the number of first gate capping patterns 125 disposed on the upper surface GS_US of the gate structure may be the same as the number of active patterns. The first gate capping patterns 125 disposed on the upper surface GS_US of the gate structure may be disposed to be spaced apart in the second direction D2.

The first side wall 125_SW1 of the first gate capping pattern 125 may contact the etching stop film 185. The second side wall 125_SW2 of the first gate capping pattern 125 may be disposed on the second gate capping pattern 145. In some embodiments, a residual insulating film 130_1 may be disposed on the second side wall 125_SW2 of the first gate capping pattern 125. The residual insulating film 130_1 may be the same material as the gate insulating film 130. A boundary between the residual insulating film 130_1 and the gate insulating film 130 disposed at the uppermost end of the gate structure GS may not be distinguished. Although the upper surface of the residual insulating film 130_1 and the upper surface 125_US of the first gate capping pattern 125 are shown as being disposed on the same plane, the embodiment is not limited thereto. For example, the upper surface of the residual insulating film 130_1 may be lower than the upper surface 125_US of the first gate capping pattern 125.

In FIGS. 2 and 3, in a portion in which the gate structure GS is positioned above the first sheet pattern NS1 in the third direction D3, a height from the upper surface BP1_US of the first lower pattern BP1 to the upper surface GS_US of the gate structure GS may be a first height H1 (height H1 in FIG. 3 is shown from the perspective of upper surface BP2_US of the second lower pattern BP2 for clarity). The upper surface GS_US of the gate structure GS may be a surface that contacts the lower surface 125_BS of the first gate capping pattern 125. The height from the upper surface BP1_US of the first lower pattern BP1 to the upper surface GS_US of the gate structure may be a second height H2 at the portion in which the gate structure GS is positioned above the field insulating film 105 in the third direction D3. In the semiconductor device according to some embodiments, the first height H1 may be greater than the second height H2.

At the portion in which the gate structure GS is positioned above the second sheet pattern NS2 in the third direction D3, the height from the upper surface BP2_US of the second lower pattern to the upper surface GS_US of the gate structure may be greater than the second height H2 (this height is also depicted as H1).

When the upper surface GS_US of the gate structure includes a concave curved surface, the second height H2 may be a height of the lowest portion of the upper surface GS_US of the gate structure GS at the portion in which the gate structure GS is positioned above the field insulating film 105 in the third direction D3.

The first active pattern AP1 will be described as an example, and the corresponding description may be applied to the second active pattern AP2 and/or other active patterns that may be implemented. A portion of the gate structure GS may be disposed between the uppermost first sheet pattern NS1 and the first gate capping pattern 125. The gate insulating film 130 may extend along the lower surface 125_BS of the first gate capping pattern 125. In other words, a portion of the gate insulating film 130 may be disposed between the lower surface 125_BS of the first gate capping pattern 125 and the gate electrode 120.

The first gate capping pattern 125 may include, for example, an insulating material. The first gate capping pattern 125 may include, for example, at least one of silicon nitride (SiN), silicon oxide (SiO₂), silicon oxynitride (SiON), silicon oxycarbonitride (SiOCN), silicon boronitride (SiBN), silicon oxyboronitride (SiOBN), silicon oxycarbide (SiOC), and combinations thereof.

At the portion in which the gate structure GS is above the field insulating film 105 in the third direction D3, the gate spacer 140 may be disposed on the side wall GS_SW of the gate structure GS. The gate spacer 140 may extend along the side wall GS_SW of the gate structure GS.

In the semiconductor device according to some embodiments, the gate spacer 140 may not be disposed either between the first lower pattern BP1 and the first sheet pattern NS1, or between the first sheet patterns NS1 adjacent to each other in the third direction D3. The gate spacer 140 may not be disposed on the first gate capping pattern 125. The gate spacer 140 may not overlap the first gate capping pattern 125 in the third direction D3.

An upper surface 140_US of the gate spacer 140 may contact the second gate capping pattern 145. In the semiconductor device according to some embodiments, the upper surface 140_US of the gate spacer 140 may be lower than the upper surface 125_US of the first gate capping pattern 125 in the third direction D3.

The gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the gate spacer 140 is shown to be a single film, embodiments are not limited thereto.

The first source/drain pattern 150 may be disposed on the first active pattern AP1. The second source/drain pattern 250 may be disposed on the second active pattern AP2. The first source/drain pattern 150 is described below. The second source/drain pattern 250 may include features similar to those described below with respect to the first source/drain pattern 150, and repeated descriptions may be omitted.

The first source/drain pattern 150 may be disposed on the first lower pattern BP1. The first source/drain pattern 150 may be connected to the first sheet pattern NS1. The first source/drain pattern 150 may contact the first sheet pattern NS1. The first source/drain pattern 150 may connect the first sheet patterns NS1 that are spaced apart in the first direction D1.

The first source/drain pattern 150 may be disposed on at least one side of the gate structure GS. The first source/drain patterns 150 may be disposed between the gate structures GS adjacent in the first direction D1. For example, the first source/drain patterns 150 may be disposed on both sides of the gate structure GS. The first source/drain pattern 150 is disposed on one side of the gate structure GS and may not be disposed on the other side of the gate structure GS.

The first source/drain pattern 150 may be included in a source/drain of a transistor that uses the first sheet pattern NS1 as a channel region.

The first source/drain pattern 150 may be disposed in the source/drain recess 150R. The source/drain recess 150R may extend in the third direction D3. The source/drain recess 150R may be defined between the gate structures GS adjacent to each other in the first direction D1.

For example, a bottom surface of the source/drain recess 150R may be defined by the first lower pattern BP1. The side walls of the source/drain recess 150R may be defined by the first sheet pattern NS1 and the inter-gate structures INT_GS1, INT_GS2, INT_GS3 and INT_GS4. A portion of the side walls of the source/drain recesses 150R may be defined by the gate structure GS between the uppermost first sheet pattern NS1 and the first gate capping pattern 125. In the semiconductor device according to some embodiments, the side walls of the inter-gate structures INT_GS1, INT_GS2, INT_GS3 and INT_GS4 may be defined by the gate insulating films 130 of the inter-gate structures INT_GS1, INT_GS2, INT_GS3 and INT_GS4.

Between the lowermost first sheet pattern NS1 and the first lower pattern BP1, the boundary between the gate insulating film 130 and the first lower pattern BP1 may be an upper surface BP1_US of the first lower pattern BP1. In other words, the upper surface BP1_US of the first lower pattern BP1 may be a boundary between the fourth inter-gate structure INT_GS4 and the first lower pattern BP1. The bottom surface of the source/drain recess 150R is lower than the upper surface BP1_US of the first lower pattern BP1.

The first source/drain pattern 150 may be disposed inside the source/drain recess 150R. The first source/drain pattern 150 may fill or at least partially fill the source/drain recess 150R.

The first source/drain pattern 150 may contact the first sheet pattern NS1 and the first lower pattern BP. The inter-gate structures INT_GS1, INT_GS2, and INT_GS3 may contact the first source/drain pattern 150. The gate structure GS between the uppermost first sheet pattern NS1 and the first gate capping pattern 125 may contact the first source/drain pattern 150.

The first source/drain patterns 150 may include an epitaxial pattern. The first source/drain pattern 150 may include a semiconductor material.

The first source/drain pattern 150 may include, for example, as silicon or germanium which is an elemental semiconductor material. Also, the first source/drain pattern 150 may include, for example, a binary compound or a ternary compound including at least two or more of carbon (C), silicon (Si), germanium (Ge), and tin (Sn), or a compound obtained by doping these elements with a group IV element. For example, the first source/drain pattern 150 may include, but is not limited to, silicon, silicon-germanium, germanium, silicon carbide, and the like.

The first source/drain pattern 150 may include impurities doped into the semiconductor material. The doped impurities may include, but are not limited to, at least one of boron (B), phosphorus (P), carbon (C), arsenic (As), antimony (Sb), bismuth (Bi) and oxygen (O).

Although the first source/drain pattern 150 is shown to be a single film, embodiments are not limited thereto.

Although the first source/drain pattern 150 is shown to have the same width in the first direction D1, embodiments are not limited thereto.

In the semiconductor device according to some embodiments, the width of the first source/drain pattern 150 in the first direction D1 may increase and then decrease, as the distance from the first lower pattern BP1 in the third direction D3 increases.

In the semiconductor device according to some embodiments, the width of the first source/drain pattern 150 in the first direction D1 may be greater than the width of the etching stop film 185 in the first direction D1. The width of the first source/drain pattern 150 in the first direction D1 may correspond to the width between the first sheet patterns NS1 adjacent to each other in the first direction D1.

In the semiconductor device according to some embodiments, the upper surface 150_US of the first source/drain pattern 150 may be lower than the upper surface GS_US of the gate structure GS, when measured from the upper surface BP1_US of the first lower pattern BP1. However, embodiments are not limited thereto. For example, when measured from the upper surface BP1_US of the first lower pattern BP1, the upper surface 150_US of the first source/drain pattern 150 may be the same as or higher than the upper surface GS_US of the gate structure GS.

When measured from the upper surface BP1_US of the first lower pattern BP1, a height H3 of the upper surface 150_US of the first source/drain pattern 150 may be lower than the height H1 of the upper surface GS_US of the gate structure GS.

In some embodiments, when measured from the upper surface BP1_US of the first lower pattern BP1, the height H3 of the upper surface 150_US of the first source/drain pattern 150 may be the same as or greater than the height H1 of the upper surface GS_US of the gate structure GS.

The etching stop film 185 may extend along the side walls 145_SW of the second gate capping pattern 145, the upper surface of the field insulating film 105, and the profile of the first source/drain pattern 150. The upper surface 185_US of the etching stop film 185 may be higher than the upper surface 125_US of the first gate capping pattern 125 when measured from the first lower pattern BP1. The upper surface 185_US of the etching stop film 185 may be coplanar with the upper surface 145_US of the second gate capping pattern 145.

The etching stop film 185 may include a material having an etching selectivity with respect to an interlayer insulating film 190, which will be described below. The etching stop film 185 may include, for example, at least one of silicon nitride (SiN), silicon oxide (SiO₂), silicon oxynitride (SiON), silicon oxycarbonitride (SiOCN), silicon boronitride (SiBN), silicon oxyboronitride (SiOBN), silicon oxycarbide (SiOC), and combinations thereof.

The interlayer insulating film 190 may be disposed on the etching stop film 185. The interlayer insulating film 190 may be disposed on the first source/drain pattern 150. The interlayer insulating film 190 may not cover or may only partially cover the upper surface 145_US of the second gate capping pattern 145 and the upper surface 140_US of the gate spacer 140. For example, the upper surface of the interlayer insulating film 190 may be coplanar with the upper surface 145_US of the first gate capping pattern 145.

The interlayer insulating film 190 may include, for example, at least one of silicon oxide, silicon nitride, silicon oxynitride, and a low dielectric constant material. The low dielectric constant material may include, for example, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica or combinations thereof.

A gate contact 170 may be disposed on the gate electrode 120. The gate contact 170 may pass through the first gate capping pattern 125 and the second gate capping pattern 145. The gate contact 170 may be connected to the gate electrode 120.

In the semiconductor device according to some embodiments, the gate contact 170 may be connected to the gate electrode 120 at the portion in which the gate structure GS is positioned over the first sheet pattern NS1 in the third direction D3. However, embodiments are not limited thereto. For example, the gate contact 170 may be connected to the gate electrode 120 at the portion in which the gate structure GS is positioned over the field insulating film 105 in the third direction D3.

A source/drain contact 175 may be disposed on the first source/drain pattern 150. The source/drain contact 175 may pass through the interlayer insulating film 190 and the etching stop film 185. The source/drain contact 175 may be connected to the first source/drain pattern 150.

The source/drain contact 175 may be disposed on the second source/drain pattern 250 and connected to the second source/drain pattern 250.

A silicide film may be disposed between the source/drain contact 175 and the source/drain patterns 150 and 250. The silicide film may include, for example, a metal silicide material.

An upper surface 175_US of the source/drain contact 175 may be higher than the upper surface 125_US of the first gate capping pattern 125 when measured from the lower pattern BP1. The upper surface 175_US of the source/drain contact 175 may be coplanar with the upper surface 170_US of the gate contact 170. However, embodiments are not limited thereto. The upper surface 170_US of the gate contact 170 may be higher than the upper surface 175_US of the source/drain contact 175.

The gate contact 170 and the source/drain contact 175 each include a conductive material, and may include, for example, at least one of a metal, a metal nitride, a metal carbonitride, a 2D material, and a conductive semiconductor material.

Although the gate contact 170 and the source/drain contact 175 are each shown as being a single film, embodiments are not limited thereto. As an example, at least one of the gate contact 170 and the source/drain contact 175 may include a contact barrier film, and a contact filling film that fills or at least partially fills a space defined by the contact barrier film.

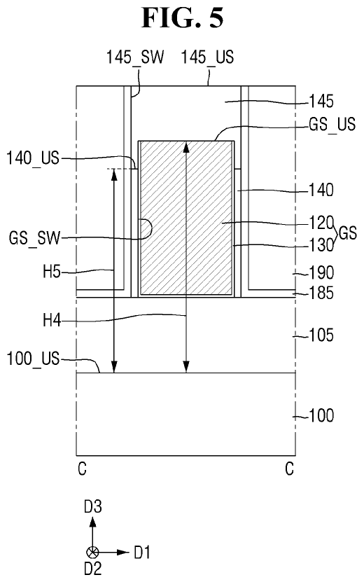

FIG. 5 is a diagram illustrating a semiconductor device according to some embodiments. FIG. 5 includes features similar to those describe above with respect to FIGS. 1-4, and repeated descriptions may be omitted.

Referring to FIG. 5, the upper surface 140_US of the gate spacer 140 may be disposed in a plane different from the upper surface GS_US of the gate structure GS at the portion that is positioned over the field insulating film 105. As shown, the upper surface 140_US of the gate spacer 140 may be lower than the upper surface GS_US of the gate structure GS.

When measured from the upper side 100_US of the substrate 100, a height H4 to the upper surface GS_US of the gate structure GS may be greater than a height H5 to the upper surface US of the gate spacer 140.

The upper surface 140_US of the gate spacer 140 may contact the second gate capping pattern 145. A portion of the second gate capping pattern 145 may contact the gate spacer 140, and may be disposed between the etching stop film 185 and the gate structure GS.

In the semiconductor device according to some embodiments, a height H4 to the upper surface GS_US of the gate structure GS may be smaller than a height H5 to the upper surface US of the gate spacer 140, when measured from the upper side 100_US of the substrate 100. Even in this case, the upper surface 140_US of the gate spacer 140 may contact the second gate capping pattern 145. That is, the second gate capping pattern 145 may cover the upper surface 140_US of the gate spacer 140.

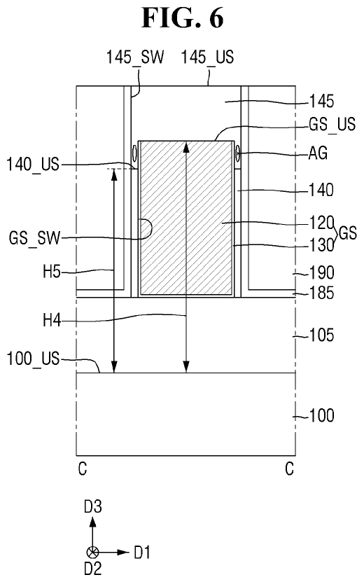

FIG. 6 is a diagram illustrating a semiconductor device according to some embodiments. FIG. 6 includes features similar to those describe above with respect to FIGS. 1-5, and repeated descriptions may be omitted.

Referring to FIG. 6, the semiconductor device according to some embodiments may include an air gap AG disposed inside the second gate capping pattern 145.

The air gap AG may be disposed between the gate structure GS and the etching stop film 185. The air gap AG may be disposed over the gate spacer 140. That is, the air gap AG may be disposed on the gate spacer 140 at a portion in which the gate structure GS and the etching stop film 185 overlap in the first direction D1. The air gap AG may be surrounded or at least partially surrounded by the second gate capping pattern 145. However, embodiments are not limited thereto.

In the semiconductor device according to some embodiments, the air gap AG may contact the gate structure GS and/or the etching stop film 185.

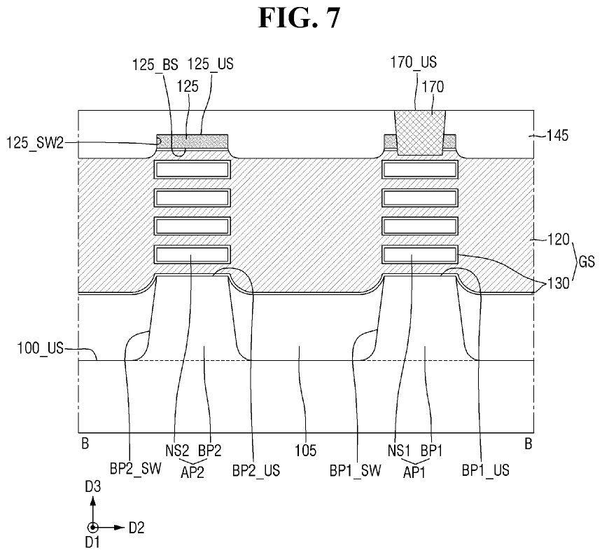

FIG. 7 is a diagram illustrating a semiconductor device according to some embodiments. FIG. 7 includes features similar to those describe above with respect to FIGS. 1-6, and repeated descriptions may be omitted.

Referring to FIG. 7, the residual insulating film 130_1 of FIG. 3 may not be formed on the second side wall 125_SW2 of the first gate capping pattern 125. The second side wall 125_SW2 of the first gate capping pattern 125 may contact the second gate capping pattern 145.

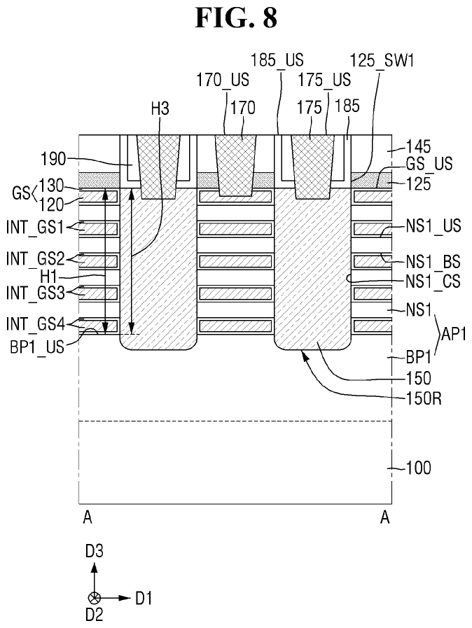

FIG. 8 is a diagram illustrating a semiconductor device according to some embodiments. FIG. 8 includes features similar to those describe above with respect to FIGS. 1-7, and repeated descriptions may be omitted.

Referring to FIG. 8, in the semiconductor device according to some embodiments, the upper surface 150_US of the first source/drain pattern 150 may be coplanar with the upper surface GS_US of the gate structure, when measured from the upper surface BP1_US of the first lower pattern BP1.

When measured from the upper surface BP1_US of the first lower pattern BP1, the height H3 of the upper surface 150_US of the first source/drain pattern 150 may be equal to the height H1 of the upper surface GS_US of the gate structure GS.

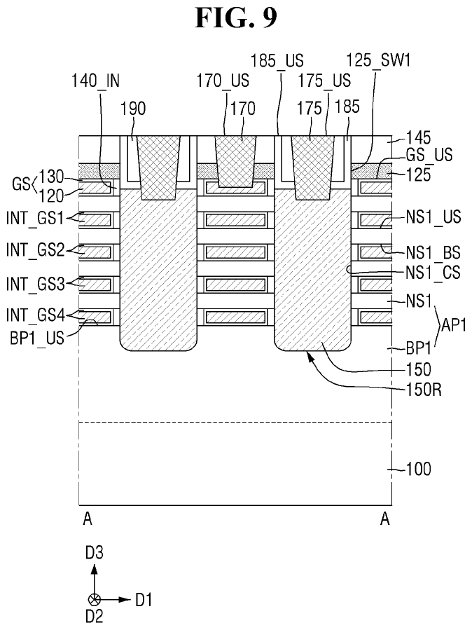

FIG. 9 is a diagram illustrating a semiconductor device according to some embodiments. FIG. 9 includes features similar to those describe above with respect to FIGS. 1-8, and repeated descriptions may be omitted.

Referring to FIG. 9, the semiconductor device according to some embodiments may further include an inner spacer 141 disposed between the gate structure GS and the first source/drain pattern 150.

The inner spacer 141 may be disposed between the inter-gate structures INT_GS1, INT_GS2, INT_GS3 and INT_GS4 and the first source/drain pattern 150. The side wall of the source/drain recess 150R may be defined by the inner spacer 141.

The inner spacer 141 may contact the gate structure GS between the uppermost first sheet pattern NS1 and the first gate capping pattern 125. The inner spacer 141 may contact the inter-gate structures INT_GS1, INT_GS2, INT_GS3 and INT_GS4. The inner spacer 141 may contact the first source/drain pattern 150.

The inner spacer 141 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

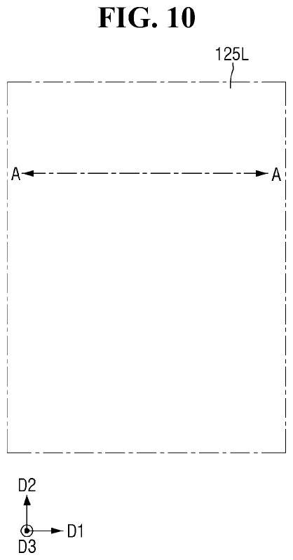

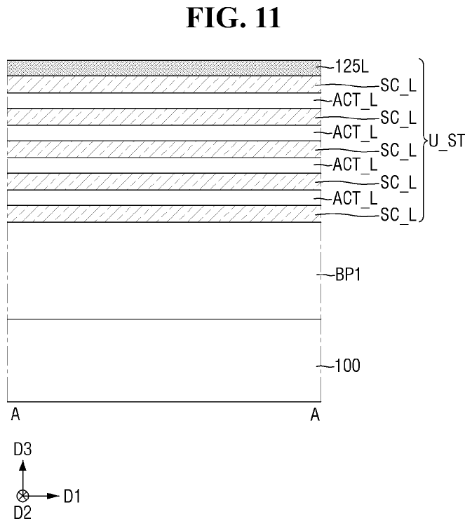

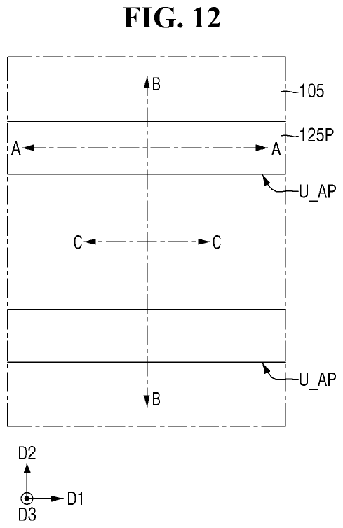

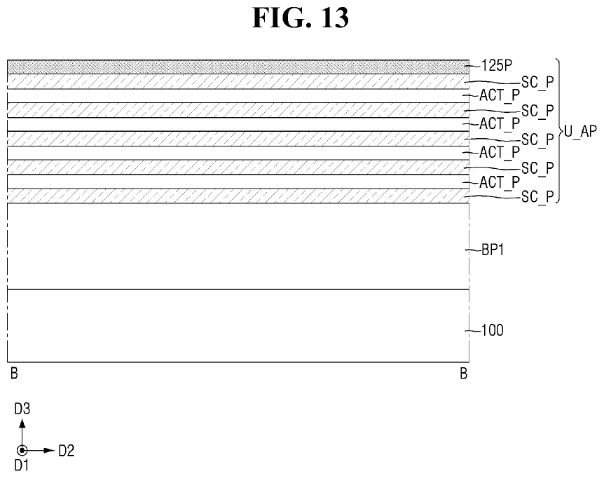

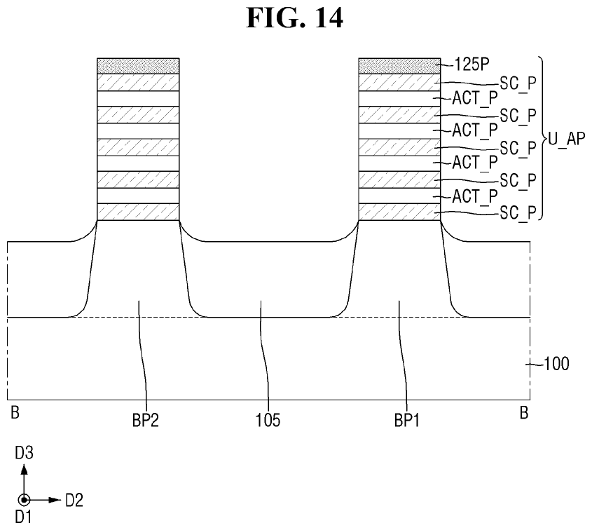

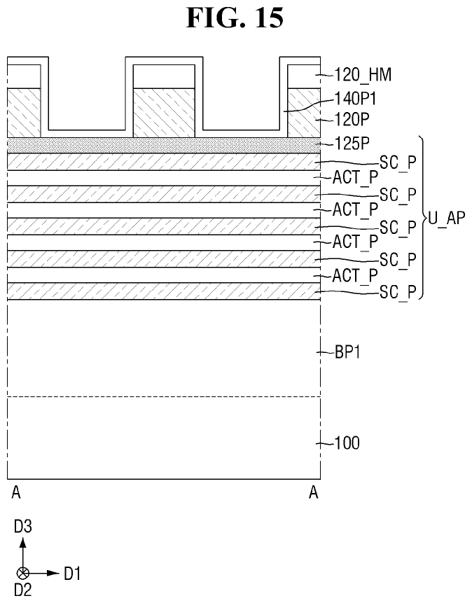

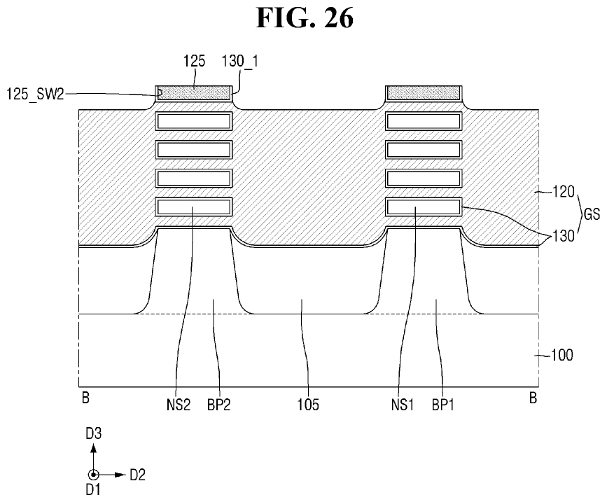

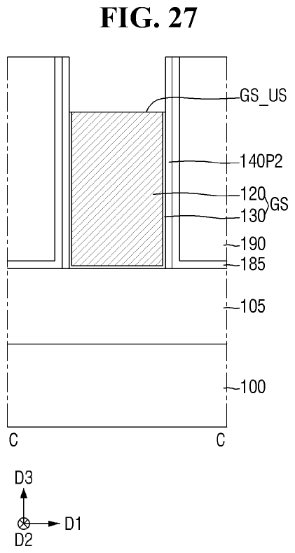

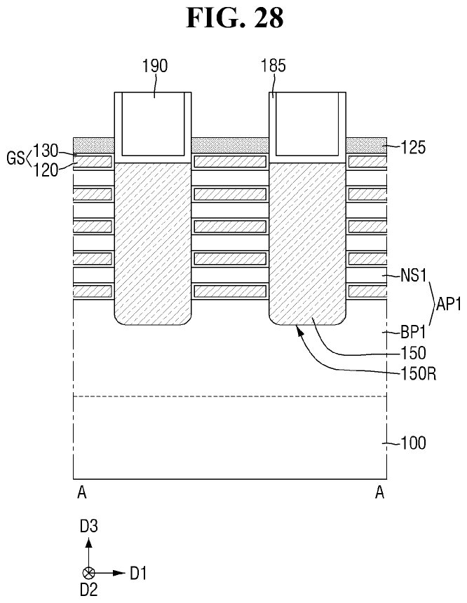

FIG. 10 to 31 are diagrams illustrating a method of fabricating a semiconductor device according to some embodiments. FIG. 11 is a cross-sectional view taken along line A-A of FIG. 10. FIGS. 15, 16, 18 to 21, 23, 25, 28 and 30 are cross-sectional views taken along line A-A of FIG. 12. FIGS. 13, 14, 17, 22, 24, 26 and 31 are cross-sectional views taken along line B-B of FIG. 12. FIGS. 27 and 28 are cross-sectional views taken along line C-C of FIG. 12.

Referring to FIGS. 10 and 11, a stacked film structure U_ST may be formed on the substrate 100.

The stacked film structure UST may include a plurality of sacrificial films SC_L and a plurality of active films ACT_L. The plurality of sacrificial films SC_L and the plurality of active films ACT_L may be alternately stacked.

The stacked film structure UST may start with the sacrificial film SC_L and end with the sacrificial film SC_L. In other words, a lowermost film of the stacked film structure UST may be the sacrificial film SC_L. An uppermost film of the stacked film structure UST may be the sacrificial film SC_L. That is, one of the plurality of sacrificial films SC_L may be the uppermost film of the stacked film structure U_ST.

For example, the sacrificial film SC_L may include a silicon-germanium film. The active film ACT_L may include a silicon film.

Subsequently, a gate etching stop film 125L may be formed on the stacked film structure U_ST.

Referring to FIGS. 12 to 14, the gate etching stop film 125L and the stacked film structure U_ST may be patterned to form a pattern structure U_AP and a pre-first gate capping pattern 125P.

The pattern structure U_AP may be formed by patterning the stacked film structure U_ST. A pre-first gate capping pattern 125P may be formed by patterning the gate etching stop film 125L. The pattern structure U_AP and the pre-first gate capping pattern 125P may each extend in the first direction D1.

The pre-first gate capping pattern 125P may be formed on the pattern structure U_AP. The pattern structure U_AP may include the sacrificial patterns SC_P and the active patterns ACT_P that are alternately stacked.

While forming the pattern structure U_AP, a portion of the substrate 100 may be etched to form a first lower pattern BP1 and a second lower pattern BP2. The pattern structure U_AP may be formed on the first lower pattern BP1 and the second lower pattern BP2.

The field insulating film 105 may then be formed on the substrate 100. The field insulating film 105 may cover or at least partially cover side walls of the first lower pattern BP1 and side walls of the second lower pattern BP2.

Referring to FIG. 15, a dummy gate electrode 120P and a dummy gate capping film 120_HM may be formed on the pattern structure U_AP.

The dummy gate electrode 120P may extend in the second direction D2.

The dummy gate electrode 120P may include, for example, polysilicon. The dummy gate capping film 120_HM may include, for example, silicon nitride.

The dummy gate electrode 120P may be formed, using the dummy gate capping film 120_HM as a mask. For example, polysilicon may be deposited on the pattern structure U_AP and patterned, using the dummy gate capping film 120_HM as a mask. The patterned polysilicon may be the dummy gate electrode 120P.

A first pre-gate spacer 140P1 may be formed on side walls of the dummy gate electrode 120P and the dummy gate capping film 120_HM.

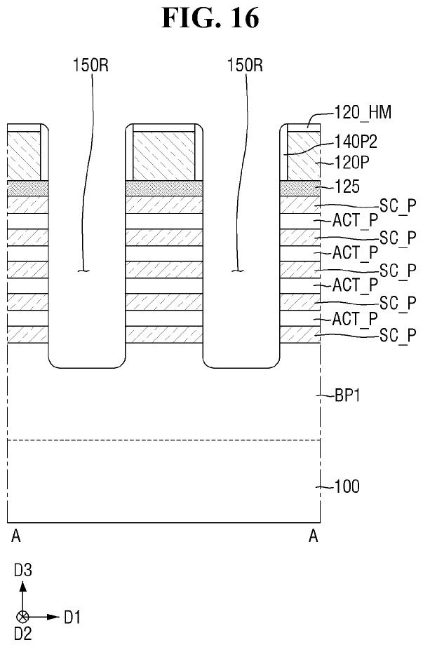

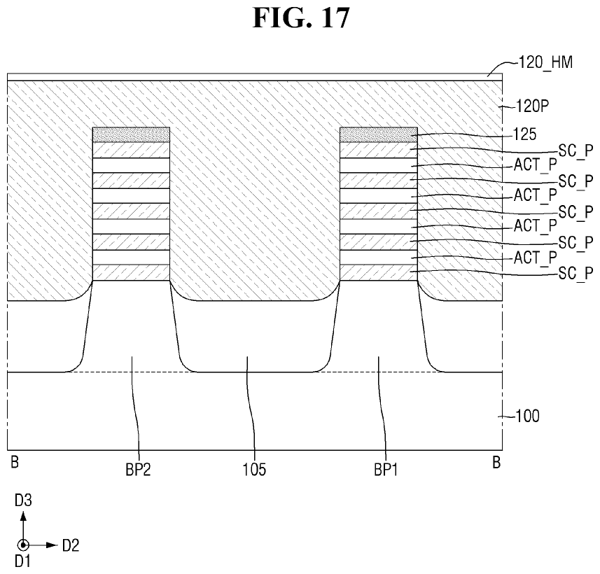

Referring to FIGS. 16 and 17, a source/drain recess 150R may be formed inside a second pre-gate spacer 140P2, a first gate capping pattern 125 and a pattern structure U_AP, using the dummy gate electrode 120P as a mask.

A portion of the source/drain recess 150R may be formed inside the first lower pattern BP1. The source/drain recess 150R may be formed on at least one side of the dummy gate electrode 120P. The thickness of the dummy gate capping film 120_HM may decrease.

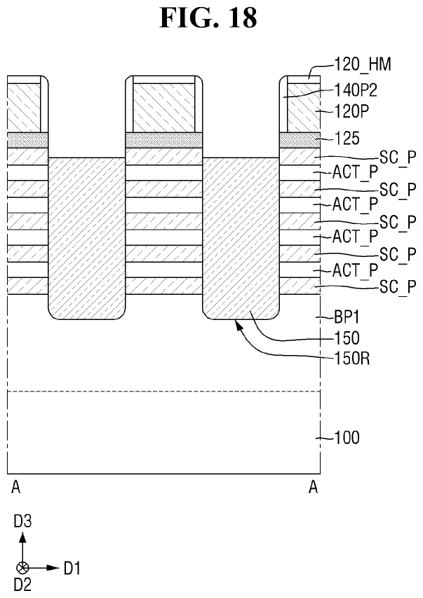

Referring to FIG. 18, the first source/drain pattern 150 may be formed inside the source/drain recess 150R. The first source/drain pattern 150 may be formed on at least one side of the dummy gate electrode 120P.

The first source/drain pattern 150 may be formed on the first lower pattern BP1. The first source/drain pattern 150 may directly contact the sacrificial pattern SC_P and the active pattern ACT_P.

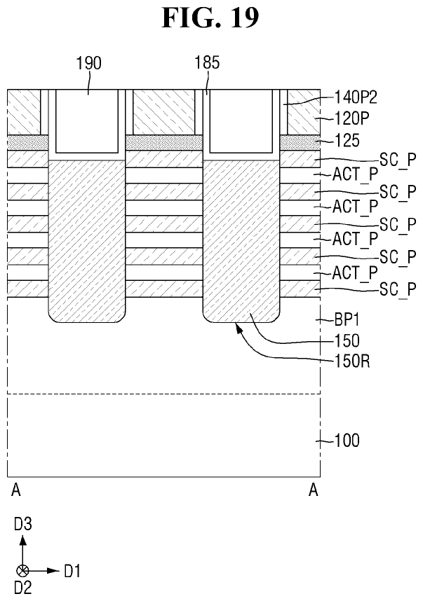

Referring to FIG. 19, an etching stop film 185 and an interlayer insulating film 190 may be sequentially formed on the first source/drain pattern 150.

While the interlayer insulating film 190 is being formed, the dummy gate capping film 120_HM may be removed to expose the upper surface of the dummy gate electrode 120P and the second pre-gate spacer 140P2.

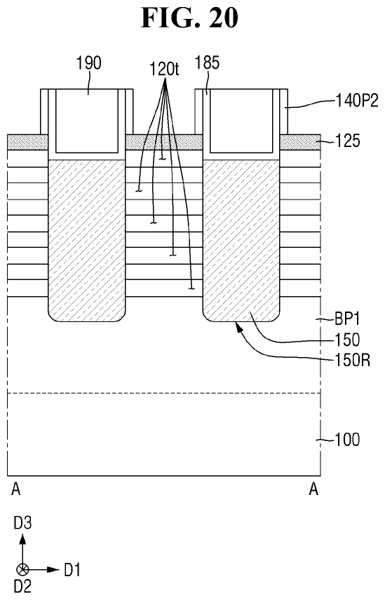

Referring to FIG. 20, the pattern structure U_AP and the first gate capping pattern 125 may be exposed by removing the dummy gate electrode 120P.

The first gate capping pattern 125 may be disposed on the upper surface of the pattern structure U_AP, but the side walls of the pattern structure U_AP may be exposed.

Then, the exposed sacrificial pattern SC_P of the pattern structure U_AP may be removed to form the first sheet pattern NS1. Accordingly, a gate trench 120t may be formed between the gate spacers 140.

Also, a first active pattern AP1 including a first lower pattern BP1 and a first sheet pattern NS1 may be formed.

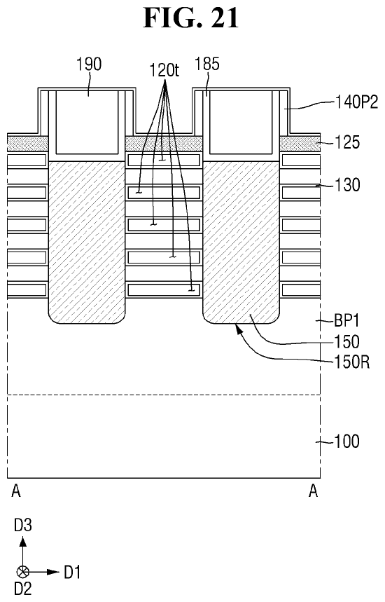

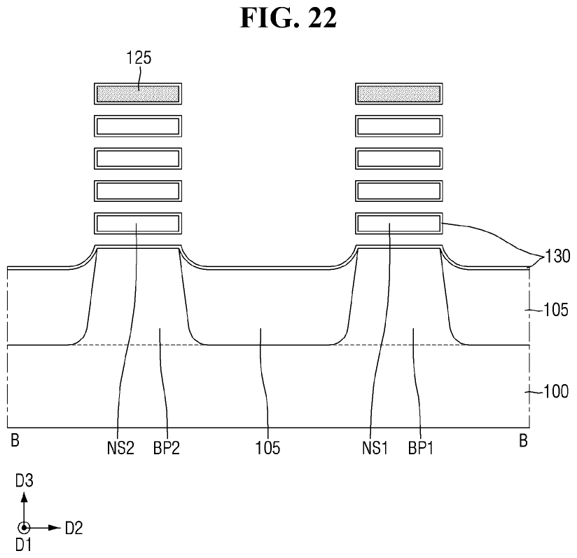

Referring to FIGS. 21 and 22, a gate insulating film 130 may be formed on the first gate capping pattern 125, the second pre-gate spacer 140P2, the etching stop film 185 and the interlayer insulating film 190. The gate insulating film 130 may be formed inside the gate trench 120t.

The gate insulating film 130 may be formed on the upper surface and side walls of the first gate capping pattern 125. The gate insulating film 130 may surround or at least partially surround the first gate capping pattern 125.

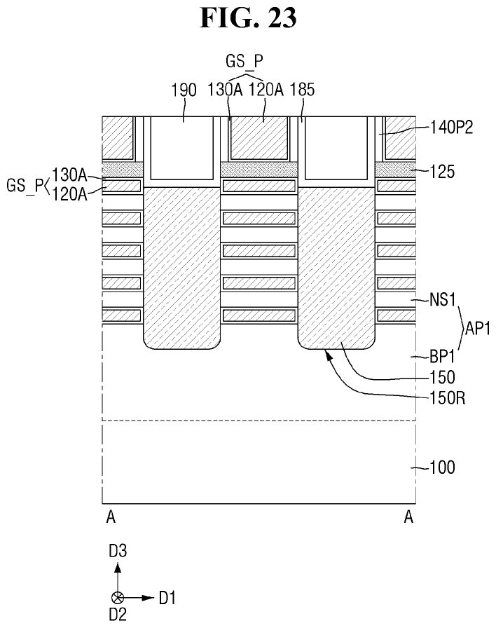

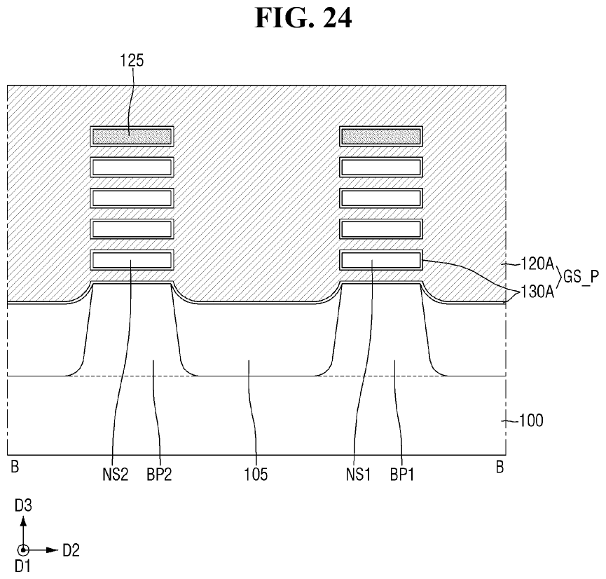

Referring to FIGS. 23 and 24, a pre-gate structure GS_P that surrounds or at least partially surrounds the first sheet pattern NS1 may be formed inside the gate trench 120t.

The pre-gate structure GS_P may cover or at least partially cover the first gate capping pattern 125. A portion of the pre-gate structure GS_P may be formed between the second pre-gate spacers 140P2.

The pre-gate structure GS_P may include a pre-gate insulating film 130A and a pre-gate electrode 120A.

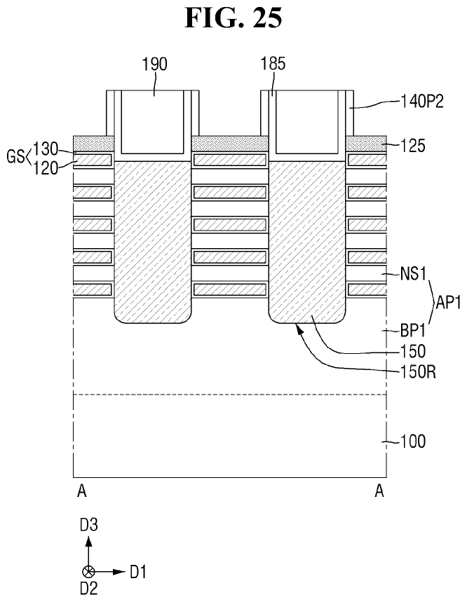

Referring to FIGS. 25 to 27, a portion of the pre-gate structure GS_P may be etched to expose the first gate capping pattern 125.

A portion of the pre-gate structure GS_P may be removed to form the gate structure GS that surrounds or at least partially surrounds the first sheet pattern NS1.

A portion of the pre-gate insulating film 130A may be removed to form a residual insulating film 130_1. The residual insulating film 130_1 may be formed on the second side walls 125_SW2 of the first gate capping pattern 125.

When removing a portion of the pre-gate structure GS_P, the residual insulating film 130_1 may be removed together.

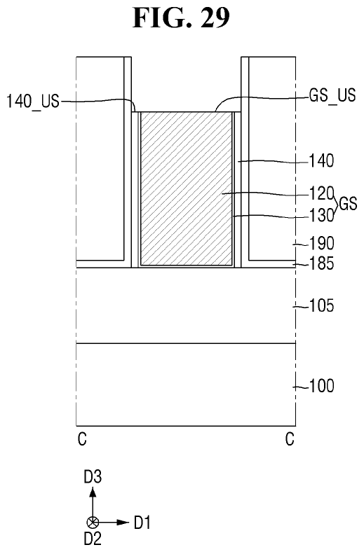

Referring to FIGS. 28 and 29, the gate spacer 140 may be formed by removing a portion of the second pre-gate spacer 140P2. An upper portion of the second pre-gate spacer 140P2 may be removed, and an upper surface 140_US of the gate spacer 140 may be formed. Although the upper surface 140_US of the gate spacer 140 is shown to be coplanar with the upper surface GS_US of the gate structure GS, embodiments are not limited thereto. For example, the upper surface 140_US of the gate spacer 140 may be disposed on a plane different from the upper surface GS_US of the gate structure GS.

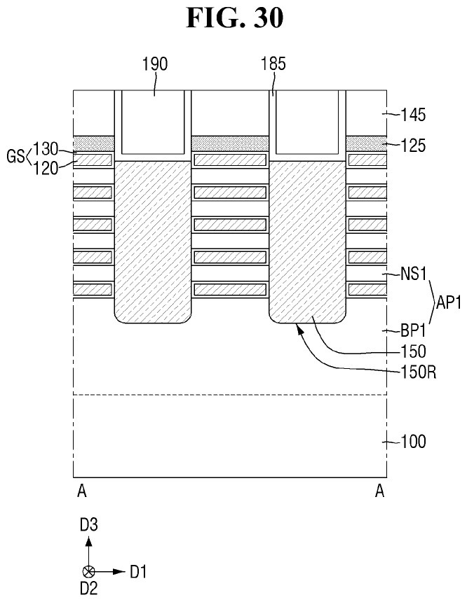

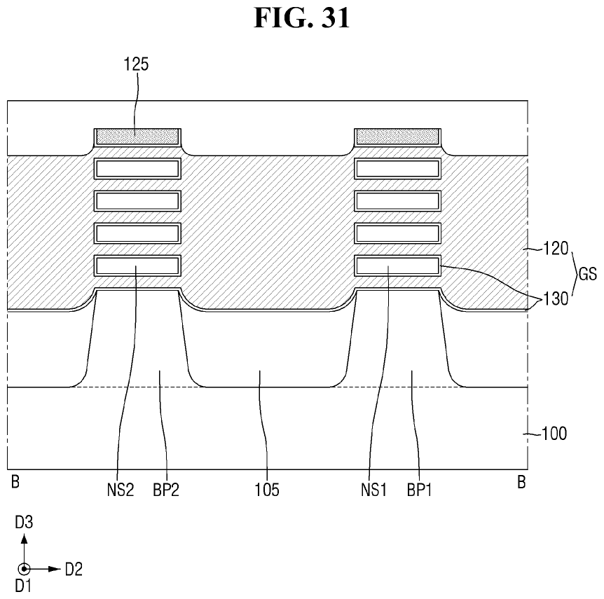

Referring to FIGS. 30 and 31, a second gate capping pattern 145 may be formed on the first gate capping pattern 125 and the gate structure GS. The second gate capping pattern 145 may fill a space from which the pre-gate structure GS_P is removed.

Next, referring to FIG. 2, the gate contact 170 and the source/drain contact 175 may be formed.

The semiconductor device according to embodiments may be a structure that does not include a top gate. The gate height may be uniformly control using a self-stopping layer, which may also act as a termination layer, thereby reducing the gate stack.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a substrate;
an active pattern comprising:
a lower pattern extending in a first direction; and
a plurality of sheet patterns above an upper surface of the lower pattern and spaced apart from the lower pattern in a second direction substantially perpendicular to the first direction;
a gate structure on the lower pattern and comprising a gate electrode and a gate insulating film, the gate electrode and the gate insulating film at least partially surrounding the plurality of sheet patterns;
a first gate capping pattern on the gate structure and above the plurality of sheet patterns in the second direction;
a gate spacer extending along a side wall of the gate structure;
a second gate capping pattern extending along an upper surface of the gate structure and an upper surface of the first gate capping pattern;
a source/drain pattern on at least one side of the gate structure; and
an etching stop film on the source/drain pattern and a first side wall of the first gate capping pattern,
wherein the second gate capping pattern at least partially covers an upper surface of the gate spacer, and
wherein, from the lower pattern, the upper surface of the first gate capping pattern is higher than the upper surface of the gate structure.

2. The semiconductor device of claim 1, further comprising:
a field insulating film at least partially covering the side wall of the lower pattern,
wherein the first gate capping pattern does not overlap the field insulating film in the second direction.

3. The semiconductor device of claim 2, wherein a first height from the upper surface of the lower pattern to the upper surface of the gate structure at a portion in which the gate structure is positioned above at least one sheet pattern of the plurality of sheet patterns is greater than a second height from the upper surface of the lower pattern to the upper surface of the gate structure at a portion in which the gate structure is positioned above the field insulating film.

4. The semiconductor device of claim 1, wherein the side wall of the second gate capping pattern contacts the etching stop film.

5. The semiconductor device of claim 1, wherein the first gate capping pattern does not overlap the gate spacer in the second direction.

6. The semiconductor device of claim 1, wherein, from the upper surface of the lower pattern, a height of the upper surface of the gate structure is different from a height of an upper surface of the source/drain pattern.

7. The semiconductor device of claim 1, wherein, from an upper surface of the substrate, a height of the upper surface of the gate structure is equal to or greater than a height of the upper surface of the gate spacer.

8. The semiconductor device of claim 1, wherein the gate structure comprises a plurality of inter-gate structures between the lower pattern and the plurality of sheet patterns, and between adjacent sheet patterns of the plurality of sheet patterns, and
wherein the source/drain pattern contacts each of the plurality of inter-gate structures.

9. The semiconductor device of claim 1, further comprising an inner spacer between the gate structure and the source/drain pattern,
wherein the gate structure comprises a plurality of inter-gate structures between the lower pattern and the plurality of sheet patterns, and between adjacent sheet patterns of the plurality of sheet patterns, and
wherein the plurality of inter-gate structures contacts the inner spacer.

10. The semiconductor device of claim 1, further comprising a source/drain contact on the source/drain pattern and connected to the source/drain pattern,
wherein, from the lower pattern, an upper surface of the source/drain contact is higher than the upper surface of the first gate capping pattern.

11. The semiconductor device of claim 1, wherein the first gate capping pattern comprises second side walls opposite to each other in a third direction intersecting the first direction, and
wherein the second side walls contact the second gate capping pattern.

12. The semiconductor device of claim 1, wherein the upper surface of the first gate capping pattern is on a first plane that is different from a second plane of an upper surface of the etching stop film.

13. A semiconductor device comprising:
a substrate;
an active pattern comprising:
a lower pattern extending in a first direction; and
a plurality of sheet patterns above an upper surface of the lower pattern and spaced apart from the lower pattern in a second direction substantially perpendicular to the first direction;
a gate structure on the lower pattern and comprising a gate electrode and a gate insulating film, the gate electrode and the gate insulating film at least partially surrounding the plurality of sheet patterns;
a first gate capping pattern on the gate structure and above the plurality of sheet patterns in the second direction;
a gate spacer extending along a side wall of the gate structure;
a second gate capping pattern extending along an upper surface of the gate structure and an upper surface of the first gate capping pattern;
a source/drain pattern on at least one side of the gate structure; and
an etching stop film on the source/drain pattern and a side wall of the first gate capping pattern,
wherein the gate structure comprises a plurality of inter-gate structures between the lower pattern and the plurality of sheet patterns, and between adjacent sheet patterns of the plurality of sheet patterns,
wherein the first gate capping pattern does not overlap the gate spacer in the second direction, and
wherein, from the lower pattern, the upper surface of the first gate capping pattern is higher than the upper surface of the gate structure.

14. The semiconductor device of claim 13, wherein the second gate capping pattern at least partially covers an upper surface of the gate spacer.

15. The semiconductor device of claim 13, further comprising an inner spacer between the gate structure and the source/drain pattern,
wherein the inner spacer contacts the plurality of inter-gate structures.

16. The semiconductor device of claim 13, wherein, from the upper surface of the lower pattern, a height of the upper surface of the gate structure is equal to or greater than a height of an upper surface of the source/drain pattern.

17. The semiconductor device of claim 13, wherein, from the lower pattern, an upper surface of the etching stop film is higher than the upper surface of the first gate capping pattern.

18. The semiconductor device of claim 13, wherein, from the substrate, an upper surface of the gate spacer is lower than an upper surface of the second gate capping pattern.

19. The semiconductor device of claim 13, further comprising: a source/drain contact on the source/drain pattern and connected to the source/drain pattern,
wherein, from the lower pattern, an upper surface of the source/drain contact is higher than the upper surface of the first gate capping pattern.

20. A semiconductor device comprising:
a substrate;
an active pattern comprising:
a lower pattern extending in a first direction; and
a plurality of sheet patterns above an upper surface of the lower pattern and spaced apart from the lower pattern in a second direction substantially perpendicular to the first direction;
a field insulating film at least partially covering a side wall of the lower pattern;
a gate structure on the lower pattern and the field insulating film, extending in a third direction, and comprising a gate electrode and a gate insulating film, the gate electrode and the gate insulating film at least partially surrounding the plurality of sheet patterns;
a first gate capping pattern on the gate structure and above the plurality of sheet patterns in the second direction;
a gate spacer extending along a side wall of the gate structure in the third direction;
a second gate capping pattern extending along an upper surface of the gate structure and an upper surface of the first gate capping pattern;
a gate contact penetrating the first gate capping pattern and the second gate capping pattern on the gate electrode, the gate contact being connected to the gate electrode;
a source/drain pattern on at least one side of the gate structure;
an etching stop film on the source/drain pattern and a side wall of the first gate capping pattern; and
a source/drain contact on the source/drain pattern and connected to the source/drain pattern,
wherein the first gate capping pattern does not overlap the field insulating film in the second direction,
wherein a second gate capping pattern at least partially covers an upper surface of the gate spacer,
wherein a side wall of the second gate capping pattern contacts the etching stop film, and
wherein, from the lower pattern, the upper surface of the first gate capping pattern is higher than the upper surface of the gate structure.
